(19) United States
(12) Patent Application Publication
(10) Pub. No.: US 2010/0330506 A1
(43) Pub. Date: Dec. 30, 2010

(54) METHOD FOR TRANSFERRING AN EPITAXIAL LAYER FROM A DONOR WAFER TO A SYSTEM WAFER APPERTAINING TO MICROSYSTEMS TECHNOLOGY

(75) Inventor: Roy Knechtel, Geraberg (DE)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: X-FAB SEMICONDUCTOR FOUNDRIES AG, Erfurt (DE)

(21) Appl. No.: 12/669,933

(22) PCT Filed: Jul. 18, 2008
(86) PCT No.: PCT/EP2008/059492

§ 371 Date: Jun. 28, 2010

(30) Foreign Application Priority Data
Jul. 21, 2007 (DE) 10 2007 025 649.5

(51) Int. Cl. G03F 7/20

(52) U.S. Cl. 430/314

(57) ABSTRACT

For bonding a donor wafer (1) and a system wafer (9) an edge bead (3) of an epitaxial layer (2) on the donor wafer is flattened or completely removed by etching so that a reliable contact after bonding up to the edge region (5, 6) is possible. The etching mask is produced by means of a resist layer (4) as well as by means of removal of resist at the edge, free exposure and developing without a special photomask.

### CROSS-REFERENCE TO RELATED APPLICATIONS

The application is a U.S. National Stage Application of International Application of PCT/EP2008/059492 filed Jul. 18, 2008, which claims the benefit of German Patent Application No. 10 2007 025 649.5 filed Jul. 21, 2007, the disclosures of which are herein incorporated by reference in their entireties.

### FIELD OF THE DISCLOSURE OF INVENTION

The invention relates to a method for transferring an epitaxial layer from a donor wafer to a system wafer in microsystem technology by means of bonding, in particular also in connection with backthinning the wafer with the epitaxial layer for applying a high quality monocrystal silicon layer on previously produced structures of the system wafer.

### BACKGROUND OF THE INVENTION

Processes wherein layers are transferred from a donor wafer to a process or system wafer by means of wafer bonding and backthinning or blow-off have been known for several years, cf. Tong & Gössele “Semiconductor Wafer Bonding”, ECS Monography ISBN 0-471-57481-3, and are now applied on an industrial scale, for example for producing 501 wafers (Silicon On Insulator Wafers). DE 102 57 097 B4 with the title “A Method for Producing Micro-Electromechanical Systems (MEMS) by Means of High Temperature Silicon Fusion Bonding” mentions also the necessity of transferring epitaxial layers by means of wafer bonding for applying silicon layers having a high quality with respect to their volume on structured wafers. In practical operation, however, bonding wafers having epitaxial layers proved to be difficult since a bead is formed on the edge of the wafer in the epitaxy process which is typical for the epitaxy process and typically cannot be prevented, neither by controlling the process nor by working the edge of the wafer prior to the epitaxy process. Due to its height this bead prevents or deteriorates bonding over a larger area extending from the edge of the wafer. Since the edge bead grows higher when the thickness of the epitaxial layer is increased, the necessary vacuum cannot be enclosed up to a distance of several centimeters from the edge when bonding an epitaxial wafer on a wafer comprising etched pits, for example, e.g. as an absolute pressure sensor substrate.

From DE-A 103 55 728 A1 with the title “A Method and Assembly for Producing Semiconductor Substrates Comprising Buried Layers by Bonding Semiconductor Wafers” a method is known wherein the wafer edge of the wafer to be bonded is mechanically worked before surface polishing. As a rule, however, this cannot be used for epitaxial wafers since mechanical working will damage the wafer surface so that bonding is no longer possible. Additional polishing would severely deteriorate the desired positive properties of the epitaxial layer, for example getter effect, lattice defects etc. so that the desired effect could no longer be obtained. It is the object of the document mentioned to enable bonding up to very close to the edge region, substantially closer than 1 mm. Furthermore, a defined brink of the edge of the transferred layer is not an important aspect of the previously mentioned technology since in the relevant applications in microsystem technology substantially larger edge exclusions are typical in most cases so that an exactly defined edge of the transferred layer is not required.

### SUMMARY OF THE INVENTION

It is an object of the invention to provide a simple and cost-effective method for suitably configuring the edge region of a layer to be transferred for enabling defined bonding of the layer up to the wafer edge.

According to the invention this object is achieved by the methods as claimed in the independent claims. Suitable structuring is provided by the absence of the etching mask in the edge region.

According to the invention, material is selectively removed from the edge region of the layer, in particular an epitaxial layer, on the basis of an etching mask in such a way that a surface topography suitable for bonding is created in the edge region. For this purpose the thickness of the layer of the etched edge region can be at least reduced with respect to its initial thickness so that the thickness of the edge is in compliance with the requirements of the subsequent bonding process.

In advantageous embodiments the thickness of the edge is selected such that it is equal to or smaller than the thickness of a region of the layer further inside which was covered by the etching mask during etching, so that between the layer of the microsystem technology wafer and the layer to be transferred a sufficient contact up to the edge region is provided in any case during bonding. Etched pits in direct vicinity to the edge region can be reliably sealed.

The methods according to the invention enable in particular unimpeded bonding up to the wafer edge by removing or at least reducing the bead of the epitaxial layer at the wafer edge which was created during the epitaxy process. According to the invention this is achieved in some embodiments through an etching process, for example a silicon etching process in the case of silicon layers, wherein in particular the etching mask can be provided very easily with respect to structuring.

According to one embodiment, a resist mask is defined for this purpose by removal of resist and free exposure of the wafer bevel.

In another advantageous embodiment this is performed without a special photomask so that a very flexible adaptation to different edge bead geometries can be done without causing extensive additional manufacturing costs.

### BRIEF DESCRIPTIONS OF THE DRAWINGS

Exemplary embodiments of the invention will now be explained and supplemented with respect to schematic illustrations in the drawing, wherein

FIG. 1 shows a cross-section of a donor wafer 1 comprising an epitaxial layer 2 with its edge bead 3.

FIG. 2 shows a plan view of the donor wafer with its epitaxial layer according to FIG. 1.

FIG. 3 shows the donor wafer with its epitaxial layer in a cross-sectional view in the two examples wherein the edge bead 3 has been removed.

FIG. 4 shows the donor wafer bonded to the system wafer 9 through the epitaxial layer (its inner region).

FIG. 5 shows the system wafer 9 with the transferred epitaxial layer 11 after the donor wafer or at least a substantial part thereof has been removed.

### DETAILED DESCRIPTION OF EXEMPLARY EMBODIMENTS

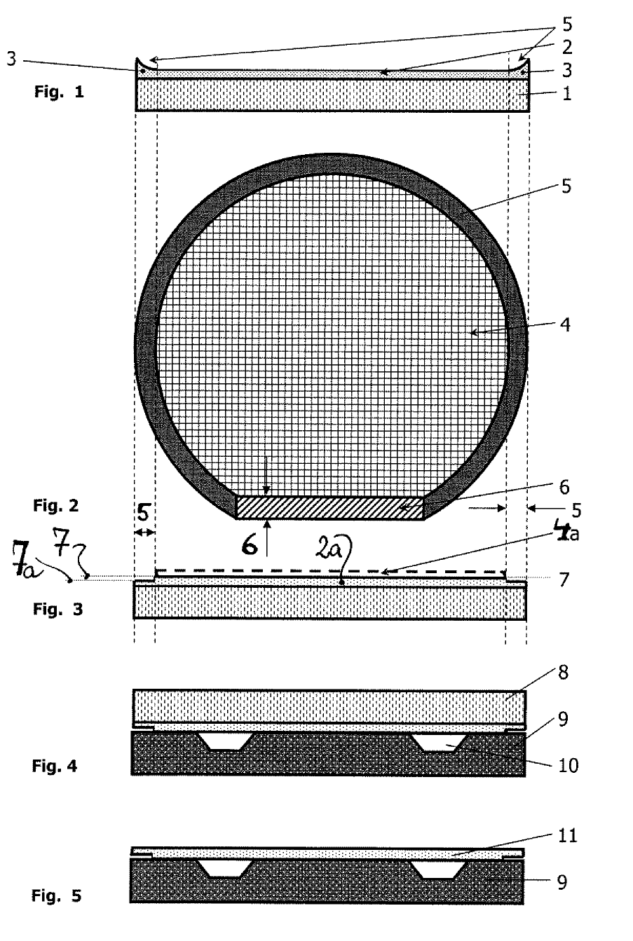

FIG. 1 shows a cross-section of a donor wafer 1 on which an epitaxial layer 2 to be transferred is provided, which layer comprises a typical edge bead 3 leading to a distinctive topography in an edge region 5. In one embodiment the epitaxial layer 2 represents a silicon layer which is grown on a silicon wafer as a donor wafer 1. The technologies disclosed herein can also be applied in connection with other materials, wherein a layer is to be transferred to a system wafer 9 by means of a wafer bonding process, wherein distinctive layer topography in the edge region 5 prevents the transfer. Thus a number of different semiconductor materials can be epitaxially grown on suitable base materials, for example, and applied and transferred to a system wafer by means of bonding. Furthermore, other depositing methods often result in unfavorable edge geometry of the layer to be transferred, and also in this case a selective adaptation of the edge geometry can be obtained by the methods disclosed herein.

FIG. 2 shows a plan view of the donor wafer 1 at a later stage of the process. For removing or at least reducing the edge bead 3 a photosensitive resist layer 4 or another viscous material is applied on the epitaxial layer 2, which is removed in the edge region 5 so that the layer 2 is exposed in the edge region 5.

In the embodiment shown the edge region comprises a curved section 5 corresponding to the curve of the donor wafer 1 as well as a straight wafer bevel 6. In other examples, the bevel 6 may not be provided and instead a notch or a similar feature for adjusting the donor wafer 1 can be provided.

In the embodiment shown the resist layer 4 is removed in the area of the curved wafer edge 5 by removing resist at the edge and in the area of the straight wafer bevel 6 by means of free exposure and developing. In other embodiments the resist layer or material layer can be removed by etching the edge, for example by selectively applying solvents etc. . . . Thus, by exposing the layer 2 at its edge an “etching mask” is produced from the resist layer 4 which is also indicated with reference numeral 4 in the following description for the sake of simplicity.

In one embodiment free exposure is performed using an exposure apparatus, for example a stepper apparatus (not shown), wherein the free exposure field is defined by the position or setting of the diaphragm of the exposure apparatus. The diaphragm position of the exposure apparatus leads to exposure or obscuration of the edge region 6 corresponding to the type of resist material used, so that the exposed or obscured part, respectively, is removed during developing. Thus, by combining removal of resist at the edge and free exposure a flexible process is provided which can be adapted to different edge bead geometries and which can be realized at low cost.

FIG. 3 shows a cross-sectional view of the donor wafer 1 and the layer 2 at an even later stage of the process. Following the production of the etching mask 4 an etching process is performed with an etching agent suitable for the layer 2 and the etching mask 4, for example on the basis of a silicon etching process when the layer 2 is made of silicon. In this way the epitaxial layer 2 is etched back to such an extent in the edge region 5, 6 which is not covered by the mask 4 that subsequently bonding is enabled without a negative influence of the edge region.

In one embodiment the edge bead 3 is etched until it disappears, i.e. the thickness of the layer in the edge region 5 or 6, respectively, is equal to the thickness of the layer in the region 2a (with the exception of process variations) which was covered previously and which is situated further inside (with respect to the edge region), i.e. “radially” inside the edge region 5. In other embodiments the thickness of the layer in the edge region 5, 6 is less than the thickness of the inner region 2a of the layer 2. A surface 7a in the edge region 5, 6 is lower than the original surface 7 of the epitaxial layer.

If the resist mask 4 is not sufficiently durable in the inner region for etching the layer 2, for example in the form of silicon etching, in case of a thicker edge bead 3 of the epitaxial layer 2, in other embodiments a previously applied hard mask 4a, for example made of silicon dioxide, is structured by means of the resist mask 4 and then used as an actual etching mask. An oxide can be produced by means of suitable oxidation processes on the layer 2, for example, and can be structured as an etching mask 4a after the resist mask has been applied. In other embodiments, other materials can be used to obtain a desired high selectivity of the etching process for removing material in the edge region 5, 6. Thus, proven materials, for example silicon nitride, silicon oxynitride etc. can be applied by means of surface treatment, depositing or such. In FIG. 3 this hard mask 4a is shown as a further example.

FIG. 4 shows a cross-sectional view at an even later stage of the process. After removal of the etching mask 4, 4a, i.e. resist mask or hard mask, the donor wafer 1 with a prepared epitaxial layer 2 having an improved edge topography is bonded with a system wafer 9 comprising pre-fabricated structures 10. In the embodiment shown the pre-fabricated structures comprise etched pits for which the layer 2 serves as a cover. Due to the improved edge topography, particularly pits 10 arranged close to the edge region 5, 6 can be reliably covered. Bonding is performed using well-known methods. Reference number 8 indicates the bonded donor wafer.

FIG. 5 shows the system wafer 9 with the layer 2 which is now indicated as transferred layer 11, wherein the donor wafer 1 or at least a major part thereof is removed. A certain part of the thickness of the layer 11 may also comprise material of the original donor wafer 1, or the thickness of the layer 11 can be smaller than the original thickness of the layer 2, depending on the corresponding way of processing.

If the layer 11 is to have the properties of the layer 2 over its entire thickness, the original thickness of the layer 2 is set in such a way that at removal of the donor wafer 1 the entire material thereof is reliably removed. If the properties of the layer are only required in contact with the structures 10, a lower thickness can be used for the layer 2 and a part of the material of the donor wafer 1 may remain on the layer 11 after removal.

Removal of the donor wafer 1 or of a substantial part thereof may be performed by thinning, for example grinding and/or etching. In other cases, the donor wafer is blown off at a desired depth which can be effected by implantation of a suitable type of atoms or ions in the desired depth and subsequent cutting by means of a beam. In this case the donor wafer 1 can be used again as a substrate for an epitaxial layer for additional system wafers.

Another embodiment relates to a method for transferring a high quality epitaxial layer 2 from a donor wafer 1 to a structured microsystem technology wafer 9 by means of wafer bonding, wherein prior to bonding the edge bead 3 of the epitaxial layer 2 resulting from the process is removed by etching. For removing the edge bead 3 a photosensitive resist layer 4 is applied on the epitaxial layer 2 which is removed in the region of the curved wafer edge 5 by means of resist removal at the edge and in the region of the straight wafer bevel 6 by means of free exposure and developing. Subsequently the epitaxial layer 2 is etched back to such an extent in the edge region 5, 6 which is not covered by the resist mask that the edge bead disappears or the corresponding edge region is lower than the original surface 7 of the epitaxial layer, respectively.

After removal of the photosensitive resist 4 the donor wafer 1 carrying the epitaxial layer 2 is joined with the system wafer 9 on the side of the system wafer structure 10 via the epitaxial layer 2 by means of bonding.

Subsequently the donor wafer 1 is removed from the epitaxial layer 2 by means of backthinning.

Still another embodiment relates to a method for transferring a high quality epitaxial layer 2 from a donor wafer 1 to a structured microsystem technology wafer 9 by means of wafer bonding, wherein prior to bonding the edge bead 3 of the epitaxial layer 2 resulting from the process is removed by etching. For removing the edge bead 3 an oxide layer is applied on the epitaxial layer 2 and a photosensitive resist layer 4 is applied thereon, which is removed in the region of the curved wafer edge 5 by means of resist removal at the edge and in the region of the straight wafer bevel 6 by means of free exposure and developing. Subsequently the oxide layer is etched off in the edge region 5, 6 which is not covered by the resist mask, whereafter the remaining resist layer 4 is removed and the oxide layer serves as protective layer for subsequent etching during which the edge bead is etched back or etched in such a way that in the edge region a level is reached which is lower than the original surface 7 of the epitaxial layer.

Thereafter the oxide layer can be removed. The donor wafer 1 with the epitaxial layer 2 is placed on the system wafer 9 (on the side of the system wafer structure 10) via the epitaxial layer 2 and is joined by means of bonding.

Subsequently the donor wafer 1 can be removed from the epitaxial layer 2 by means of backthinning.

1. A method for transferring an epitaxial layer from a donor wafer to a structured wafer in microsystem technology by means of wafer bonding, which method comprises
forming an etching mask on the epitaxial layer, wherein the etching mask does not cover an edge region of the epitaxial layer having an edge bead;
removing material of the epitaxial layer in the exposed edge region so that the edge bead of the epitaxial layer is at least reduced;
bonding the donor wafer and the structured microsystem technology wafer via the epitaxial layer;
removing at least a part of the donor wafer.

2. The method according to claim 1, wherein forming the etching mask comprises: applying resist layer and removing a part of the resist layer in the edge region.

3. The method according to claim 2, wherein removing a part of the resist layer comprises: removing the resist layer by means of resist removal at the edge in the area of a curved wafer edge and free exposure and developing in the area of a straight wafer bevel.

4. The method according to claim 3, wherein free exposure is performed by means of a stepper apparatus in which a free exposure field is defined by a position of a diaphragm or such a setting that no particular exposure mask is required.

5. The method according to claim 1, wherein forming the etching mask further comprises: forming a hard mask layer on the epitaxial layer and structuring the hard mask layer in such a way that the edge region of the epitaxial layer is exposed.

6. The method according to claim 5, wherein forming the hard mask layer comprises: producing an oxide layer on the epitaxial layer.

7. The method according to claim 5, wherein the hard mask layer is structured by means of a resist layer which is removed before removal of material of the epitaxial layer.

8. The method according to claim 1, wherein a thickness of the epitaxial layer in the edge region is smaller than or equal to a thickness of a covered inner region of the epitaxial layer after material has been removed from the epitaxial layer.

9. The method according to claim 1, wherein removing at least a part of the donor wafer comprises: backthinning the donor wafer.

10. The method according to claim 1, wherein removing at least a part of the donor wafer comprises: blowing off at least of a part of the donor wafer.

11. The method according to claim 10, wherein the blown-off part of the donor wafer is used as a new donor wafer.

12. The method according to claim 1, wherein the epitaxial layer is bonded on a structured side of the structured wafer as a microsystem technology wafer.

13. A method for transferring a layer from a donor wafer to a structured microsystem technology wafer by means of wafer bonding, which method comprises
forming an etching mask on the layer by applying a photosensitive resist layer and removing a portion of the resist layer in the area of a curved edge region by means of resist removal at the edge and in the area of the straight wafer bevel by means of free exposure and developing;
removing material of the layer in the region of the wafer bevel and of the curved wafer edge which is not covered by the etching mask;
bonding the donor wafer and the wafer of the structured microsystem technology via an inner section of the layer.

14. The method according to claim 13, wherein forming the etching mask further comprises: producing a hard mask material on the layer prior to applying the resist layer and structuring the hard mask material by means of the resist layer.

15. The method according to claim 13, wherein forming the etching mask comprises: forming a resist mask from the resist layer and using the resist mask as an etching mask.

16. The method according to claim 13, wherein free exposure is performed using a stepper apparatus without a specific exposure mask wherein the diaphragm setting is adjusted.

17. The method according to claim 13, further comprising: backthinning the donor wafer after bonding to the microsystem technology wafer.

18. The method according to claim 13, further comprising: blowing off the donor wafer.

19. The method according to claim 13, wherein the layer after removal of material comprises a thickness in the edge region which is smaller than a thickness in a region of the layer covered by the etching mask.

20. The method according to claim 13, wherein the layer is bonded to a side of the wafer of the microsystem technology comprising etched pits as structures.

21. The method according to claim 13, wherein the layer is produced by epitaxy on the donor wafer.

22. The method according to claim 13, wherein the layer is a high quality monocrystal silicon layer.

23. The method according to claim 19, wherein the region of the layer which is not covered is situated radially inside the edge region.

24. The method according to claim 13, wherein the removal of material of the layer in its edge region is performed by means of a silicon etching process.

25. The method according to claim 1, wherein the removal of material of the layer in its edge region is performed by means of a silicon etching process.
